(19) United States
(12) Patent Application Publication
(10) Pub. No.: US 2005/0053849 A1
(43) Pub. Date: Mar. 10, 2005

(54) Electrochemical fabrication method for producing compliant beam-like structures

(75) Inventors: Adam L. Cohen, Los Angeles, CA (US); Michael S. Lockard, Lake Elizabeth, CA (US); Christopher A. Bang, San Diego, CA (US); Marvin M. Kilgo III, Oakland, CA (US)

Correspondence Address: Microfabrica Inc., 1103 W. Isabel St., Burbank, CA, 91506, US

(73) Assignee: Microfabrica Inc., Burbank, CA (US)

(21) Appl. No.: 10/883,891

(22) Filed: Jul. 2, 2004

Related U.S. Application Data
(60) Provisional application No. 60/484,636, filed on Jul. 3, 2003.

(51) Int. Cl. G03F 9/00

(52) U.S. Cl. 430/5

(57) ABSTRACT

Embodiments of the invention are directed to the formation of beam-like structures using electrochemical fabrication techniques where the beam like structures have narrow regions and wider regions such that a beam of desired compliance is obtained. In some embodiments, narrower regions of the beam are thinner than a minimum feature size but are formable as a result of the thicker regions. In some embodiments the beam-like structures are formed from a plurality of adhered layers.

### RELATED APPLICATIONS

This application claims benefit of U.S. Provisional Patent Application No. 60/484,636 filed on Jul. 3, 2003. This referenced application is hereby incorporated herein by reference as if set forth in full.

### FIELD OF THE INVENTION

The embodiments of various aspects of the invention relate generally to the formation of three-dimensional structures using electrochemical fabrication methods via a layer-by-layer build up of deposited materials and more particularly to the formation of beam-like structures that have a desired compliance.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. It is being commercially pursued by Microfabrica™ Inc. (formerly MEMGen® Corporation) of Burbank, Calif. under the name EFAB®. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica™ Inc. (formerly MEMGen® Corporation) of Burbank, Calif. such masks have come to be known as INSTANT MASKS™ and the process known as INSTANT MASKING or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
(1) A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p161, August 1998.
(2) A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p244, January 1999.
(3) A. Cohen, “3-D Micromachining by Electrochemical Fabrication”, Micromachine Devices, March 1999.
(4) G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., April 1999.
(5) F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
(6) A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
(7) F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
(8) A. Cohen, “Electrochemical Fabrication (EFABTM)”, Chapter 19 of The MEMS Handbook, edited by Mohamed Gad-El-Hak, CRC Press, 2002.
(9) Microfabrication—Rapid Prototyping's Killer Application”, pages 1 -5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

The '630 patent also teaches that other methods may be used to form contact masks (i.e. electroplating articles in the language of the '630 patent) which include applying masking composition selectively to a support by such processes as screen printing, stencil printing and inkjet printing.

The '630 patent also teaches that methods similar to those used in relief printing can also be used to fabricate electroplating articles (i.e. contact masks). A cited example of such a method includes: applying a liquid masking composition to a relief pattern, which might be produced by patterning a high aspect ratio photoresist such as AZ4620 or SU-8; pressing the relief pattern/masking composition structure against a support such that the masking composition adheres to the support; and removing the relief pattern. The formed electroplating article includes a support having a mask patterned with the inverse pattern of the relief pattern.

The '630 patent additionally teaches the creation of an electroplating article (i.e. a contact mask) by creating a relief pattern on a support by etching of the support, or applying a durable photoresist, e.g., SU-8; coating a flat, smooth sheet with a thin, uniform layer of liquid masking composition; stamping the support/resist against the coated sheet (i.e., like a stamp and inkpad) to quickly mate and unmate the support/resist and the masking composition (preferably the support and the sheet are kept parallel); and curing the liquid masking composition.

In addition to teaching the use of CC masks for electrodeposition purposes, the '630 patent also teaches that the CC masks may be placed against a substrate with the polarity of the voltage reversed and material may thereby be selectively removed from the substrate. It indicates that such removal processes can be used to selectively etch, engrave, and polish a substrate, e.g., a plaque.

The '630 patent further indicates that the electroplating methods and articles disclosed therein allow fabrication of devices from thin layers of materials such as, e.g., metals, polymers, ceramics, and semiconductor materials. It further indicates that although the electroplating embodiments described therein have been described with respect to the use of two metals, a variety of materials, e.g., polymers, ceramics and semiconductor materials, and any number of metals can be deposited either by the electroplating methods therein, or in separate processes that occur throughout the electroplating method. It indicates that a thin plating base can be deposited, e.g., by sputtering, over a deposit that is insufficiently conductive (e.g., an insulating layer) so as to enable subsequent electroplating. It also indicates that multiple support materials (i.e. sacrificial materials) can be included in the electroplated element allowing selective removal of the support materials.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

### SUMMARY OF THE INVENTION

It is an object of some aspects of the invention is to provide one or more beam-like structures having desired values of compliance which are greater than normally considered possible.

Other objects and advantages of various aspects of the invention will be apparent to those of skill in the art upon review of the teachings herein. The various aspects of the invention, set forth explicitly herein or otherwise ascertained from the teachings herein, may address one or more of the above objects alone or in combination, or alternatively they may address some other object of the invention that may be ascertained from the teachings herein. It is not necessarily intended that all objects be addressed by any single aspect of the invention even though that may be the case with regard to some aspects.

In a first aspect of the invention an elongated structure having a desired compliance, includes a structural material that is deposited configured with narrow regions separated by wider regions, wherein the widths of the regions are selected to yield desired mechanical properties.

In a second aspect of the invention a method of designing a structure, includes: designing the structure to one or more beam-like elements and to have a desired set of mechanical properties; comparing the dimensions of the designed structure with minimum feature size dimensions and determining that a width of at least one of the beam-like elements is narrower than a minimum feature size; modifying the configuration of at least one beam-like element that has a width narrower than the minimum feature size by, configuring portions of the one beam-like element to have a width greater than the minimum feature size and other portions of the beam-like element to have widths greater than the minimum feature size.

In a third aspect of the invention a method for producing a multi-layer structure having an elongated element having an effective compliance, includes: configuring a design of the elongated element to have portions that have widths less than a minimum feature size and portions having widths greater than the minimum feature size wherein a compliance of the structure is set at or below a desired amount; and producing the structure using masking operations and electrochemical deposition operations, where the formation of the masks or the use of the masks at least in part dictate the minimum feature size.

Further aspects of the invention will be understood by those of skill in the art upon reviewing the teachings herein. Other aspects of the invention may involve combinations of the above noted aspects of the invention and/or addition of various features of one or more embodiments. Other aspects of the invention may involve apparatus that can be used in implementing one or more of the above method aspects of the invention. These other aspects of the invention may provide various combinations of the aspects presented above as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself.

FIG. 5A depicts a top view of a beam which is too narrow to be formed but which offers a desired compliance.

FIGS. 5B-5D depict beams of similar length dimension to that shown in FIG. 5A but which have been modified according to various embodiments of the invention to include hold-down structures which enhance manufacturability.

FIG. 5E depicts a straight beam with a larger cross-sectional width than that of the beam of FIG. 5A such that the beam is manufacturable without hold-downs but which doesn't offer a desired level of compliance.

FIGS. 5F-5G depict beams of similar dimension to that shown in FIG. 5A but which have been modified according to a various embodiments of the invention to include hold-down structures which enhance manufacturability.

FIG. 6 depicts a structure containing multiple compliant beams that include hold-down structures.

FIG. 7 depicts a multi-layer beam structure where the hold-down elements are adhered to previous hold-down elements while the thin portions of the beams may delaminate from one another.

FIG. 8 depicts a top view of an alternative beam structure where the hold-downs for the main beam structure are also joined by a secondary beam structure which may be used to tailor or control deflection of the main beam structure.

FIG. 9 depicts a top view of a further alternative embodiment where the size and positions of the hold-down elements are varied to tailor the mechanical properties of the beam.

FIGS. 10A-10E depict top views of five example beam-like structures that have a desired compliance and furthermore have features that limit the amount of deflection (in the plane of the page) that the beam-like structures can undergo or cause a change in compliance when a certain deflection amount is reached.

### DETAILED DESCRIPTION OF THE PREFERRED EMBODIMENTS OF THE INVENTION

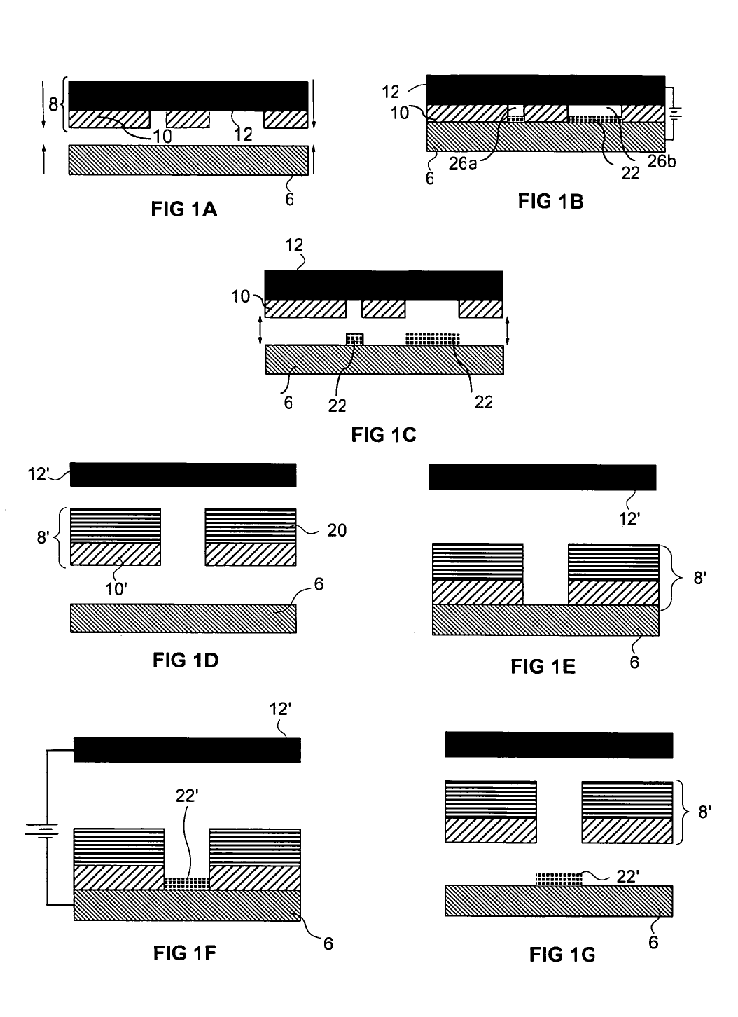

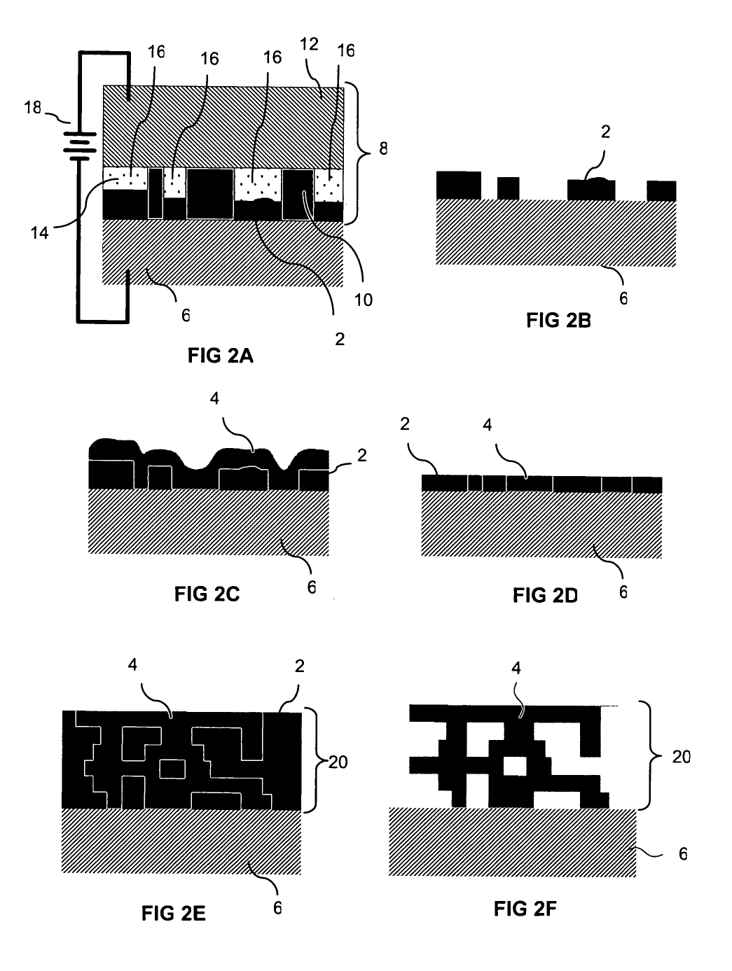

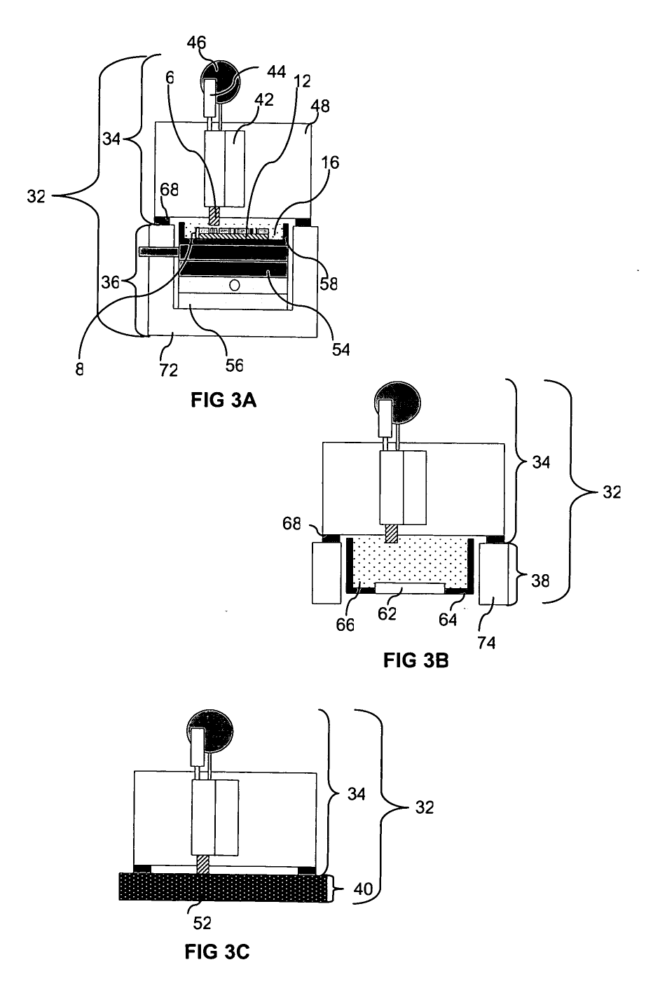

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

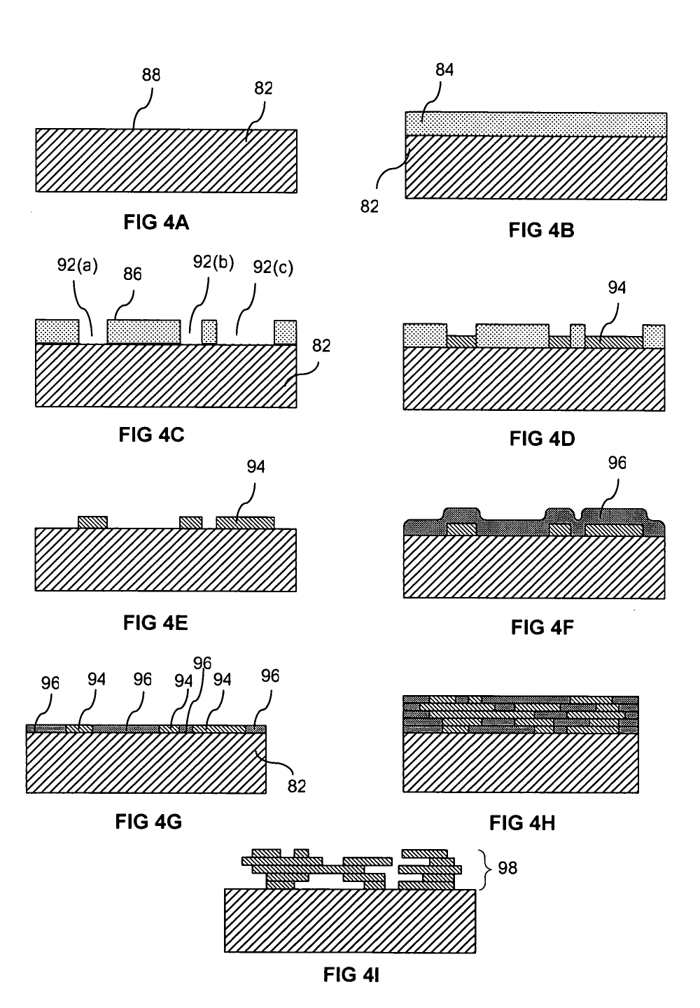

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

Various embodiments of various aspects of the invention are directed to formation of three-dimensional structures from materials some or all of which are to be electrodeposited. Some of these structures may be formed form a single layer of one or more deposited materials while others are formed from a plurality of layers of deposited materials (e.g. 2 or more layers, more preferably five or more layers, and most preferably ten or more layers). In some embodiments structures having features positioned with micron level precision and minimum features size on the order of tens of microns are to be formed. In other embodiments structures with less precise feature placement and/or larger minimum features may be formed. In still other embodiments, higher precision and smaller minimum feature sizes may be desirable.

Various embodiments of the invention may perform selective patterning operations using conformable contact masks and masking operations, proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), and/or adhered masks and masking operations (masks and operations that use masks that are adhered to a substrate onto which selective deposition or etching is to occur as opposed to only being contacted to it). Adhered masks may be formed in a number of ways including (1) by application of a photoresist, selective exposure of the photoresist, and then development of the photoresist, (2) selective transfer of pre-patterned masking material, and/or (3) direct formation of masks from computer controlled depositions of material.

Various embodiments of the present invention are directed to the design of structures which include at least one narrow beam-like feature where the effective width of the beam-like feature is less than that generally considered to be reliably formable wherein the formation of the narrow feature is controlled by the selective deposition of material via a patterned mask (e.g. of the contact, proximity, or adhered type) or the selective etching via a patterned mask. In other words, various embodiments of the invention are directed to formation of structures having one or more features that have dimensions that are smaller than a minimum feature size, MFS. The MFS may vary based on the specifics of the formation process but is generally related to the ability to reliably form masks of desired patterning and to use those masks in depositing either a sacrificial or structural material or in etching a material in anticipation of filling created voids with a sacrificial or structural material. The MFS, for example, may be defined as the minimum width of a structure of defined length (e.g. 100-500 microns) that may be reliably formed (e.g. 90-99 times out of 100).

Various embodiments of the invention are directed to the formation of structures that, after formation and removal of sacrificial material, have narrow unsupported features where the width of the structure is at least in part based on it having a desired compliance (e.g. in the plane of the layer in a direction that has a component that is parallel to the width dimension (i.e. perpendicular to the elongated portion of the structure).

As noted above, in some embodiments the formation process involves the deposition of a sacrificial material as well as a structural material on a particular layer of a structure. Some embodiments allow a much narrower beam or similar structure to be successfully fabricated than is typically considered possible. As the beam width narrows the compliance of the beam increases most particularly within the plane of the layer and perpendicular to the length of the beam. However, for example, such beams may also be designed to achieve increased compliance perpendicular to the layer plane, or to achieve a required compliance in torsion.

In various embodiments of the invention the beam-like structures are formed with alternating lengths of narrow structural material and wider structural material. The lengths of narrow structural material are designed to produce most if not all of the compliance while the wider regions are designed such that they may result in reliable formation of themselves as well as of the intervening narrower regions. They are spaced within a distance of each other such that the narrower portions of the structure may also be formed reliably.

A first exemplary embodiment involves the selective deposition of sacrificial material using a patterned photoresist (or similar material) to define the pattern of openings for receiving a sacrificial material. After deposition of the sacrificial material, the resist is removed, and a deposition of structural material occurs. The deposition of structural material is typically performed in a blanket deposition manner but may be selectively deposited in some alternative embodiments. In embodiments where blanket deposition occurs, and even in some embodiments where selective deposition of structural material occurs, a planarization operation is performed to bring the net height of deposition to a desired level. In these embodiments, the pattern of structural material is initially manifest in the photoresist. For example, a beam that is to be formed out of nickel can be produced by patterning a beam in photoresist, plating sacrificial material (e.g., copper), stripping the resist, plating nickel, and then planarizing. For this process to work, the resist needs to adhere reasonably well to the substrate (or to a previously formed layer), since if it detaches and is washed away (e.g., during developing, processing related to developing, or plating) the beam will not be formed and the area intended to be occupied by resist and later by structural material will be occupied by sacrificial material. Similarly, the photoresist must be completely removed prior to the deposition of structural material, else structural material will not be deposited in at least some desired regions and the desired structure will not be properly formed.

It is observed that as features are designed smaller (e.g., as a beam is designed narrower) at some size, the resist (i.e. patterning material) will no longer remain reliably attached and the feature cannot be manufactured. Loss of the resist features may make it impossible to manufacture structures such as beams which are narrow enough, and thus sufficiently compliant, for the intended application.

According to some embodiments narrow beam structures are designed to include one or more wider “hold-down” features. These embodiments provide a method for designing and forming structures that can be manufactured with narrower elongated features and with greater compliance than would otherwise be possible, by providing ‘hold-down’ features which prevent loss of the narrower patterned resist structures.

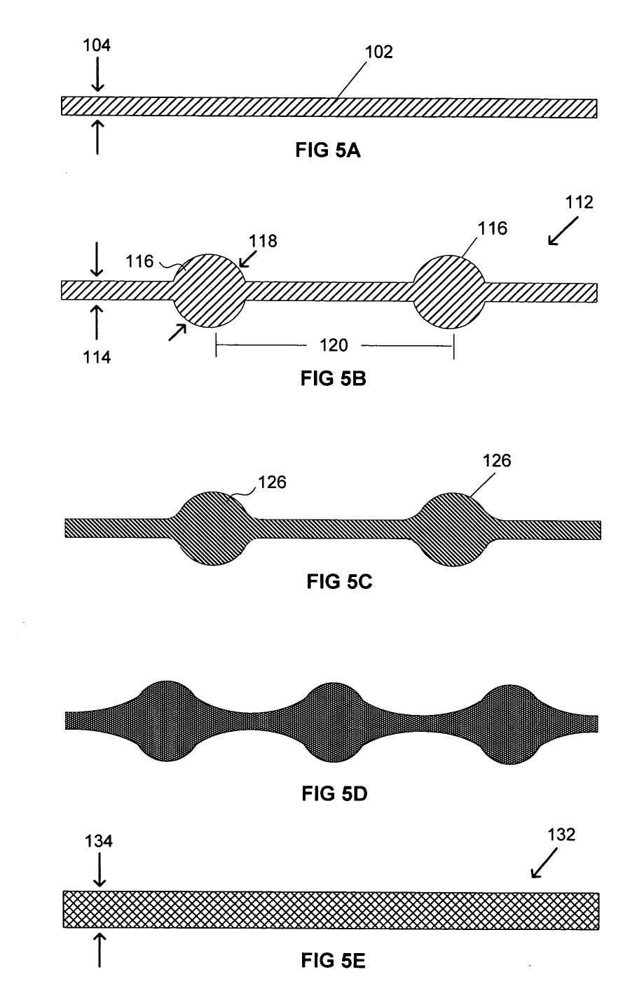

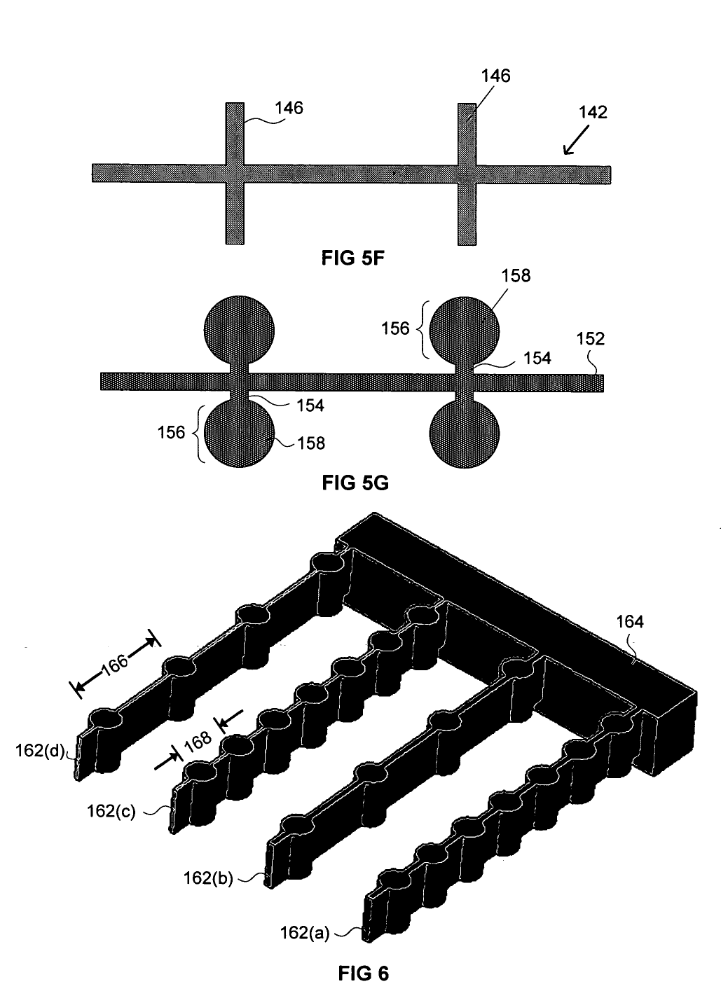

FIG. 5A shows a top view (i.e. perpendicular to the plan of the layer or layers) of a narrow beam 102. It is assumed that such a beam is narrow enough that it would not be manufacturable due to loss of the corresponding patterning structure, i.e. its width 104 is less than the MFS.

FIG. 5B shows a top view of a beam 112 having a width 114 which is similar to the width 104 of the beam of FIG. 5A, but which is provided with hold-down features 116 which have widths 118 which are greater than the MFS. In the example of FIG. 5B the hold-down features are shown as being circular and thus the width 118 corresponds to a diameter of the circular structure. The width 118 of the hold-down features is made as small as possible while the center-to-center spacing is made as large as possible. If it is desired that the beam of FIG. 5B has the same compliance as that of FIG. 5A, the narrow portions of the beam of FIG. 5B may be made some what smaller than the width 104 of the beam of FIG. 5A to account for diminished compliance associated with the portion of the beam length which is occupied by hold-down features and which offer little or no compliance.

FIG. 5C depicts a beam 122 having hold-down features with an alternative configuration. The hold-down features 126 still have a generally circular configuration but with fillets that form a smooth transition between the hold-down feature and the narrow portion of the beam. It is believed that this structure will reduce stress concentrations during compliant movement. In still other embodiments the tapering may continue through a large portion of the narrow portion of the beam if not the entire length of the narrow portion of the beam as indicated in FIG. 5D.

The hold-downs of FIGS. 5B-5D are intended to provide additional area to attach the patterning structure to the substrate during processing, thereby preventing total loss of the resist structure (i.e. at least minimizing excessive misplacement of the narrowest portions of the patterning structure). In some cases, the hold-downs may even prevent delamination of the narrowest portions of the patterning material and thus improve the likelihood of adhesion between the narrowest structural material on the present layer with structural material located on a previous layer.

The beams of FIGS. 5B-5D are very compliant due to their effective narrow widths. They may not be quite as compliant as the beam of FIG. 5A due to the low compliance of the hold-downs, but as indicated above the compliance may increased by making the beams of FIGS. 5B-5D have segments that are somewhat narrower than that of FIG. 5A. In any event, the beams of FIGS. 5B-5D are more compliant than the uniformly-wide beam 132 shown in top view in FIG. 5E. The beam in FIG. 5E has a length similar to those of the beams of FIGS. 5B-5D but is designed wide enough to avoid loss of the resist structure. The width 134 of the beam 132 may be similar to the width of the hold-down structures 116 and 126 of FIGS. 5B and 5C or may be somewhat narrower if hold-downs of FIGS. 5B and 5C required some additional increment in width to reliably remain in place as a result of their shorter length.

For a given length beam it is within the skill of the art to determine the width (e.g. empirically) that is required to reliably form a beam. Similarly for a given post or hold-down structure it is within the ability of those of skill in the art to determine the required dimensions for the structure so it will stay attached to a substrate or previously formed layer whether the substrate or previously formed layer comprises structural material or a sacrificial material that will eventually be removed.

FIG. 5F shows a top view of a single or multi-layer beam 142 with hold-downs 146 of a different design. In this example, the hold-down features are narrower than those in FIG. 5B, thus making the beam more compliant than that of the FIG. 5B. However, the hold-downs are themselves thin and may therefore not serve the retention function as well as may be desired under some circumstances.

If experimentation shows that sufficiently narrow hold-downs (e.g. similar to those of FIG. 5F do not offer sufficient robustness to the build process, the hold-downs 156 may include relatively narrow side runners 154 and larger post-like structures that do not themselves directly contact the beam 152 which is to have improved compliance. An example of such a structure is shown in FIG. 5G. In the embodiment of FIG. 5G, the hold-downs 156 will not interfere with the bending of the beam 152 unless the bend radius is very small.

In other embodiments the hold-down structures may take on shapes that are other than circular in nature. For example, they may have square or rectangular configurations or diamond shaped configurations. In still other embodiments the position or shape of the hold-downs need not be symmetric about the beam. For example, in some embodiments the hold-downs may be located on a single side of the beam or they may be located on alternating sides of the beam.

FIG. 6 provides a perspective view of four relatively tall beams 162(a)-162(d) which are made from structural material and that are equipped with hold-downs similar to those shown in FIG. 5B. These beams may be formed from multiple adhered layers. These four beams connect at one end to a support structure 164 which may be adhered to structural material associated with previous layers (not shown) or to subsequent layers (not shown). These beams are shown with two different hold-down spacings 166 and 168. The fewer the hold-downs (or the further apart they are spaced), the better for compliance. But the greater the number of hold-downs (or the more closely they are spaced), the better for retention. In a given situation, the best compromise between reliable formation and compliance can be determined experimentally.

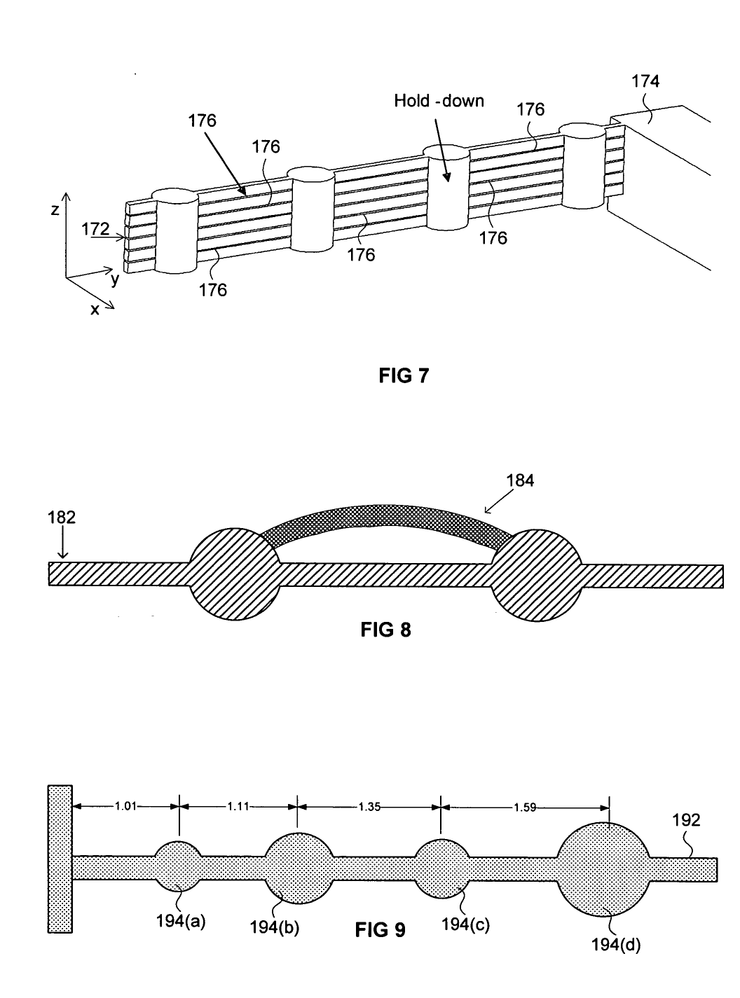

FIG. 7 provides a perspective view of a beam 172 which is similar to beam 162(d) of FIG. 6 and which is formed from 6 layers of structural material and is adhered to a support 174. Here however it is assumed that the narrow portions of the resist structure (though not the hold-downs themselves) delaminated from the substrate and there was therefore some deposition of sacrificial material beneath them (i.e., a ‘flash’ deposit). The presence of sacrificial material between layers in the narrow portions of the beam gives rise to thin gaps 176 between portions of the layers (after removal of the sacrificial material). These gaps may not substantially affect the mechanical performance of the beam as a whole and particularly with regard to deflections in the positive or negative X direction. Thus even if the narrow portions of the beam delaminate and allow some under-deposition of the sacrificial material, as long as the mask that patterns the beam is properly formed and remains in place in a more-or-less undistorted position, a satisfactory working compliant beam can be fabricated.

Beams made according to various embodiments of the invention can be arbitrarily tall (especially if made from multiple layers), thus making them extremely stiff in the direction perpendicular to the plane of the substrate and very compliant within the plane of the substrate.

In some embodiments, beams may be formed in combination with different structural elements that can be used to tailor the mechanical properties of the beam or to provide preferential bending locations and the like. In some embodiments, the beams may have portions with varying widths such that some portions provide less compliance than others. In other embodiments, as shown in FIG. 8, additional or secondary beam-like elements 184 may be added to stiffen the primary beam 182 at specific locations so as to tailor bending to occur at desired locations. In the example of FIG. 8, the added beam-like element 184 is coplanar with at least one layer of the primary beam, but may have a different total height than the primary beam 182. If the location of the secondary beam is appropriately selected it may be possible for a deflection along the planes of the layers of the beam to translated into an out of plane motion of the beam.

In other embodiments, the mechanical properties of the beam may be tailored by varying the size and spacings of the hold-down elements and even of the beam itself. FIG. 9. illustrates a beam 192 having hold-downs 194(a)-194(d) that vary in size and spacing.

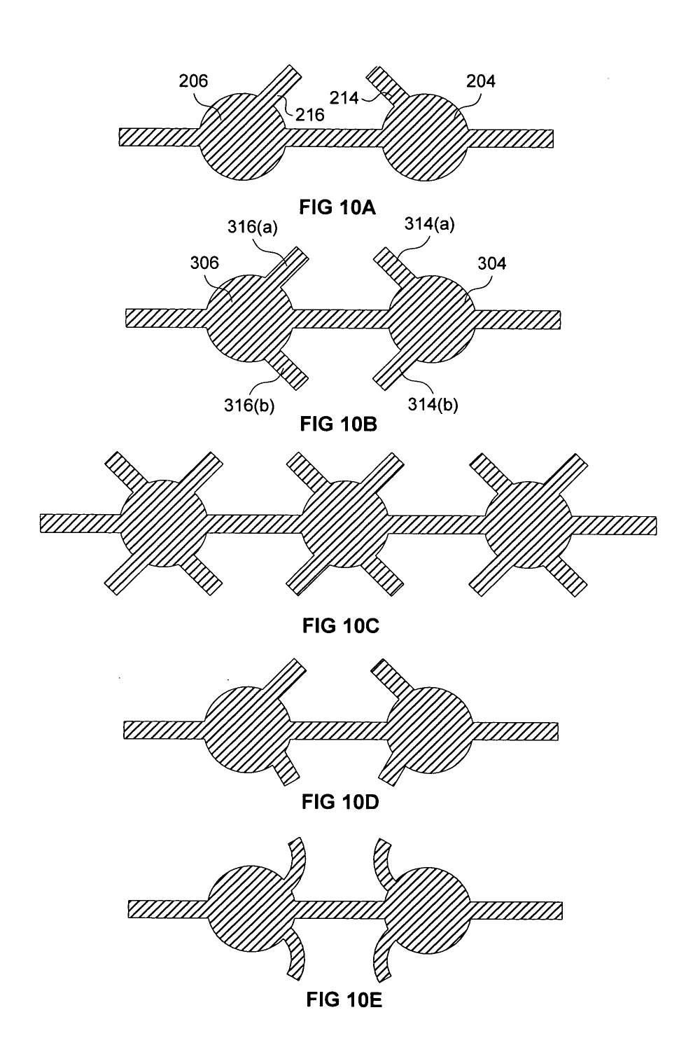

In other embodiments, beams may be formed in combination with different structural elements that can be used to set deflection limits or can be use to set controlled changes in compliance when certain deflection amounts occur. For example, FIG. 10A provides a top view of a structure that includes two hold down features 204 and 206 that includes stubs 214 and 216, respectively, which extend from the same respective side of each hold down feature. These stubs 214 and 216 may be used to limit the amount of deflection that the intermediate portion of the beam can undergo when bending upward in the plane of the layer. As FIG. 10A does not include stubs on the opposite side of the hold down elements, greater deflection is allowed when the beam bends in that direction. In other embodiments, the stubs need not be supplied in a symmetric or identical opposing fashion. FIG. 10B depicts an alternative embodiment, where stubs 314(a) & (b) and 316(a) & (b) extend from both sides of the hold down structures 304 and 306. FIG. 10C depicts another example, where three hold down features exist where the central hold down structure includes four stubs (two on one side of the beam and two on the other side). FIG. 10D depicts another alternative example where the stubs on either side of the beam are of different lengths and thus set different deflection limits depending direction of bending. FIG. 10E depicts a further alternative where instead of the stubs providing a hard stop when deflection reaches a certain amount, the stubs may contact and slide beside one another to allow continued bending but with a change in compliance.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, and the like.

| US Pat App No, Filing Date | |
|---|---|
| US App Pub No, Pub Date | Inventor, Title |
| 09/493,496 - Jan. 28, 2000 | Cohen, “Method For Electrochemical Fabrication” |
| 10/677,556 - Oct. 1, 2003 | Cohen, “Monolithic Structures Including Alignment |
| | and/or Retention Fixtures for Accepting Components” |
| 10/830,262 - Apr. 21, 2004 | Cohen, “Methods of Reducing Interlayer |
| | Discontinuities in Electrochemically Fabricated Three- |
| | Dimensional Structures” |
| 10/271,574 - Oct. 15, 2002 | Cohen, “Methods of and Apparatus for Making High |
| 2003-0127336A - July 10, 2003 | Aspect Ratio Microelectromechanical Structures” |
| 10/697,597 - Dec. 20, 2002 | Lockard, “EFAB Methods and Apparatus Including |
| | Spray Metal or Powder Coating Processes” |
| 10/677,498 - Oct. 1, 2003 | Cohen, “Multi-cell Masks and Methods and Apparatus |
| | for Using Such Masks To Form Three-Dimensional |
| | Structures” |
| 10/724,513 - Nov. 26, 2003 | Cohen, “Non-Conformable Masks and Methods and |
| | Apparatus for Forming Three-Dimensional Structures” |
| 10/607,931 - Jun. 27, 2003 | Brown, “Miniature RF and Microwave Components and |
| | Methods for Fabricating Such Components” |
| 10/841,100 - May 7, 2004 | Cohen, “Electrochemical Fabrication Methods |
| | Including Use of Surface Treatments to Reduce |
| | Overplating and/or Planarization During Formation of |
| | Multi-layer Three-Dimensional Structures” |
| 10/387,958 - Mar. 13, 2003 | Cohen, “Electrochemical Fabrication Method and |
| 2003-022168A - Dec. 4, 2003 | Application for Producing Three-Dimensional |
| | Structures Having Improved Surface Finish” |
| 60/533,897 - Dec. 31, 2003 | Cohen, “Electrochemical Fabrication Process for |
| | Forming Multilayer Multimaterial Microprobe |
| | Structures” |
| 10/434,494 - May 7, 2003 | Zhang, “Methods and Apparatus for Monitoring |
| 2004-0000489A - Jan. 1, 2004 | Deposition Quality During Conformable Contact Mask |
| | Plating Operations” |
| 10/434,289 - May 7, 2003 | Zhang, “Conformable Contact Masking Methods and |
| 20040065555A - Apr. 8, 2004 | Apparatus Utilizing In Situ Cathodic Activation of a |
| | Substrate” |
| 10/434,294 - May 7, 2003 | Zhang, “Electrochemical Fabrication Methods With |
| 2004-0065550A - Apr. 8, 2004 | Enhanced Post Deposition Processing Enhanced Post |
| | Deposition Processing” |
| 10/434,295 - May 7, 2003 | Cohen, “Method of and Apparatus for Forming Three- |
| 2004-0004001A - Jan. 8, 2004 | Dimensional Structures Integral With Semiconductor |
| | Based Circuitry” |
| 10/434,315 - May 7, 2003 | Bang, “Methods of and Apparatus for Molding |
| 2003-0234179 A - Dec. 25, 2003 | Structures Using Sacrificial Metal Patterns” |
| 10/772,943 - Feb. 4, 2004 | Arat, “Electrochemically Fabricated Microprobes” |
| 10/841,272 - May 7, 2004 | Cohen, “Methods and Apparatus for Forming Multi- |
| | Layer Structures Using Adhered Masks” |
| 10/841,300 - May 7, 2004 | Lockard, “Methods for Electrochemically Fabricating |
| | Structures Using Adhered Masks, Incorporating |
| | Dielectric Sheets, and/or Seed layers That Are |
| | Partially Removed Via Planarization” |
| 10/841,383 - May 7, 2004 | Lockard, “Electrochemical Fabrication Methods Using |
| | Transfer Plating of Masks” |
| 10/841,005 - May 7, 2004 | Smalley, “Electrochemical Fabrication Process Using |
| | Directly Patterned Masks” |
| 10/434,103 - May 7, 2004 | Cohen, “Electrochemically Fabricated Hermetically |
| 2004-0020782A - Feb. 5, 2004 | Sealed Microstructures and Methods of and Apparatus |
| | for Producing Such Structures” |
| 10/841,384 - May 7, 2004 | Zhang, “Method of Electrochemically Fabricating |
| | Multilayer Structures Having Improved Interlayer |
| | Adhesion” |
| 10/841,006 - May 7, 2004 | Thompson, “Electrochemically Fabricated Structures |
| | Having Dielectric or Active Bases and Methods of and |
| | Apparatus for Producing Such Structures” |
| 10/434,519 - May 7, 2003 | Smalley, “Methods of and Apparatus for |
| 2004-0007470A - Jan. 15, 2004 | Electrochemically Fabricating Structures Via Interlaced |
| | Layers or Via Selective Etching and Filling of Voids” |
| 10/724,515 - Nov. 26, 2003 | Cohen, “Method for Electrochemically Forming |
| | Structures Including Non-Parallel Mating of Contact |
| | Masks and Substrates” |
| 10/841,347 - May 7, 2004 | Cohen, “Multi-step Release Method for |
| | Electrochemically Fabricated Structures” |
| 60/533,947 - Dec. 31, 2003 | Kumar, “Probe Arrays and Method for Making” |
| 60/534,183 - Dec. 31, 2003 | Cohen, “Method and Apparatus for Maintaining |
| | Parallelism of Layers and/or Achieving Desired |
| | Thicknesses of Layers During the Electrochemical |
| | Fabrication of Structures” |
| 60/582,689 - Jun. 23, 2004 | Kruglick, “Cantilever Microprobes with Improved Base |
| | Structures and Method for Making the Same” |
| 60/582,690 - Jun. 23, 2004 | Kruglick, “Cantilever Microprobes with Base Structures |
| | Configured for Mechanical Interlocking to a Substrate” |

Various other embodiments of the present invention exist. Some of these embodiments may be based on a combination of the teachings herein with various teachings incorporated herein by reference. Some embodiments may not use any blanket deposition process and/or they may not use a planarization process. Some embodiments may use selective deposition processes or blanket deposition processes on some layers that are not electrodeposition processes. Some embodiments may use electroplating deposition process, electrophoretic depositions process, electroless deposition processes, sputtering processes, spreading processes, and the like. Some embodiments, for example, may use nickel, gold, copper, tin, silver, zinc, solder as structural materials while other embodiments may use different materials. Some embodiments, for example, may use copper, tin, zinc, solder or other materials as sacrificial materials. Some embodiments may remove all sacrificial material while other embodiments may not. Some embodiments may use photoresist, polyimide, glass, ceramics, other polymers, and the like as dielectric structural materials.

In some embodiments, two materials may be deposited in association with individual layers but additional materials may be added to the overall structure by using different pairs of materials on different layers. For example, some layers may include copper and a dielectric while other layers may include nickel and copper. After the formation of the structure is completed, the copper may be removed as a sacrificial material which leaves behind a nickel and dielectric structure with hollowed out regions and/or a nickel, dielectric, and copper structure if copper is entrapped by regions of nickel and/or dielectric material. In other embodiments, more than two materials may be deposited in association with some layers.

It will be understood by those of skill in the art that additional operations may be used in variations of the above presented embodiments. These additional operations may, for example, perform cleaning functions (e.g. between the primary operations discussed above), they may perform activation functions, they may perform monitoring functions, and the like.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

1. An elongated structure having a desired compliance, comprising a structural material that is configured with narrow regions separated by wider regions, wherein the widths of the regions are selected to yield desired mechanical properties.

2. The structure of claim 1 comprising a plurality of layers of deposited material.

3. The structure of claim 1 wherein the narrow regions have a width that is less than a general minimum feature size associated with a build process which is used in fabricating the structure and where the wider regions have a width that is greater than the general minimum feature size.

4. A method of designing a structure, comprising:
designing a structure comprising one or more beam-like elements to have a desired set of mechanical properties;
comparing the dimensions of the designed structure with minimum feature size dimensions and determining that a width of at least one of the beam-like elements is narrower than a minimum feature size;
modifying the configuration of the at least one beam-like element that has a width narrower than the minimum feature size by, configuring portions of the one beam-like element to have a width less than the minimum feature size and at least one other portion of the at least one beam-like element to have a width greater than the minimum feature size.

5. A method for producing a multi-layer structure having an elongated element having an effective compliance, comprising:
configuring a design of the elongated element to have portions that have widths less than a minimum feature size and portions having widths greater than the minimum feature size wherein a compliance of the elongated elements is set at desired amount;
producing the structure using masking operations and electrochemical deposition or etching operations, where the formation of the masks or use of the masks at least in part dictate the minimum feature size.
